(19) United States
(12) Patent Application Publication
(10) Pub. No.: US 2008/0130342 A1
(43) Pub. Date: Jun. 5, 2008

(54) Hybrid-Level Three-Dimensional Memory

(76) Inventor: Guobiao ZHANG, Carson City, NV (US)

Correspondence Address: GUOBIAO ZHANG, P.O. BOX 6182, STATELINE, NV, 89449-6182, US

(21) Appl. No.: 11/736,767

(22) Filed: Apr. 18, 2007

(30) Foreign Application Priority Data
Dec. 1, 2006 (CN) 200610162698.2

(51) Int. Cl. G11C 5/02

(52) U.S. Cl. 365/51

(57) ABSTRACT

The present invention discloses a hybrid-level three-dimensional memory (HL-3DM). Some of its memory levels are separated, i.e. there is an inter-level dielectric between adjacent memory levels; while others are interleaved, i.e. adjacent memory levels share address-selection lines. The HL-3DM is particularly suitable for 3D-M with a large number of memory levels (m).

### CROSS-REFERENCE TO RELATED APPLICATIONS

This application is related to a CHINA P. R., Patent Application 200610162698.2, “Hybrid-Level Three-Dimensional Memory”, filed Dec. 1, 2006.

### BACKGROUND

1. Technical Field of the Invention

The present invention relates to the field of integrated circuit, and more particularly to semiconductor memory.

2. Related Arts

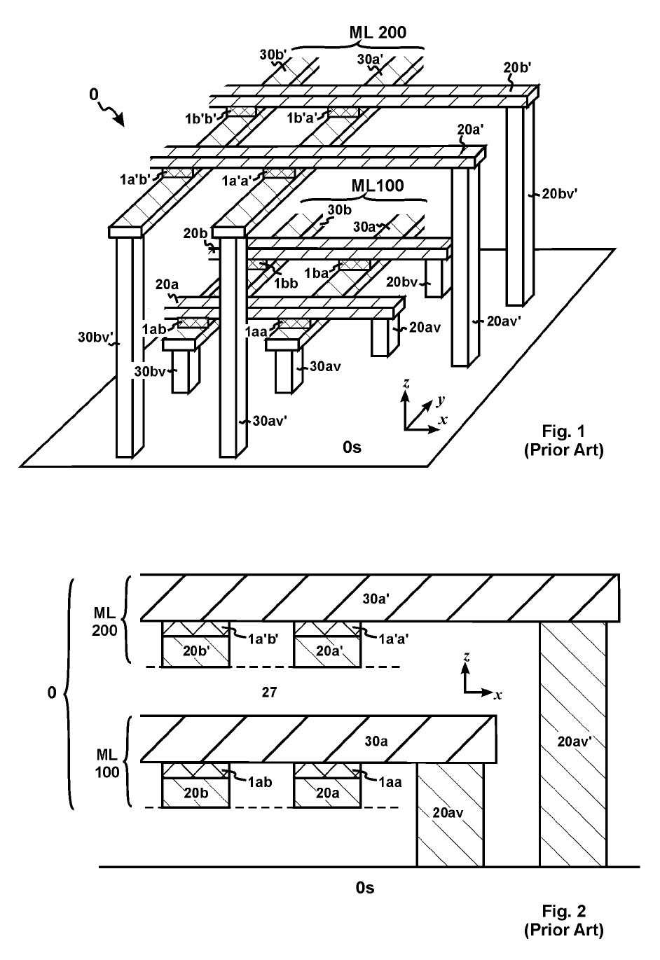

Three-dimensional memory (3D-M) comprises a plurality of vertically stacked memory levels. As illustrated in FIG. 1, this preferred 3D-M 0 comprises a substrate 0s and m memory levels (100, 200 . . . ) stacked above the substrate 0s, where m is the total number of memory levels. The substrate 0s comprises transistors and interconnects. Each memory level comprises a plurality of address-selection lines (e.g. word lines 20a, 20a′ . . . ; bit lines 30a, 30a′ . . . ) and memory cells (e.g. memory cell 1aa between word line 20a and bit line 30a, memory cell 1a′a′ between word line 20a′ and bit line 30a′ . . . ). Contact vias (20av, 20av′ . . . ) provide electrical connections between the memory levels and the substrate 0s.

3D-M can be categorized into three-dimensional random-access memory (3D-RAM) and three-dimensional read-only memory (3D-ROM). 3D-ROM can be further categorized into three-dimensional mask-programmable memory (3D-MPM) and three-dimensional electrically-programmable memory (3D-EPM). 3D-EPM could be write-many-times (e.g. 3D-flash, 3D-MRAM, 3D-FRAM, 3D-OUM) or write-once (3D-OTP). Memory cells in a 3D-M could use active devices (e.g. thin-film transistor) or passive devices (e.g. diodes).

U.S. patent application Ser. No. 11/309,657 discloses another categorization of the 3D-M. Based on the structure of its memory levels, 3D-M may be categorized into separated 3D-M (referring to FIG. 9C and FIG. 10C of the above-mentioned application) and interleaved 3D-M (referring to FIG. 9A and FIG. 10A of the above-mentioned application).

FIG. 2 illustrates a separated 3D-M. It comprises two memory levels 100, 200 (i.e. m=2) and they are separated by an inter-level dielectric 27. During read/write, the existence of the inter-level dielectric 27 ensures that there is no interference between these memory levels 100, 200.

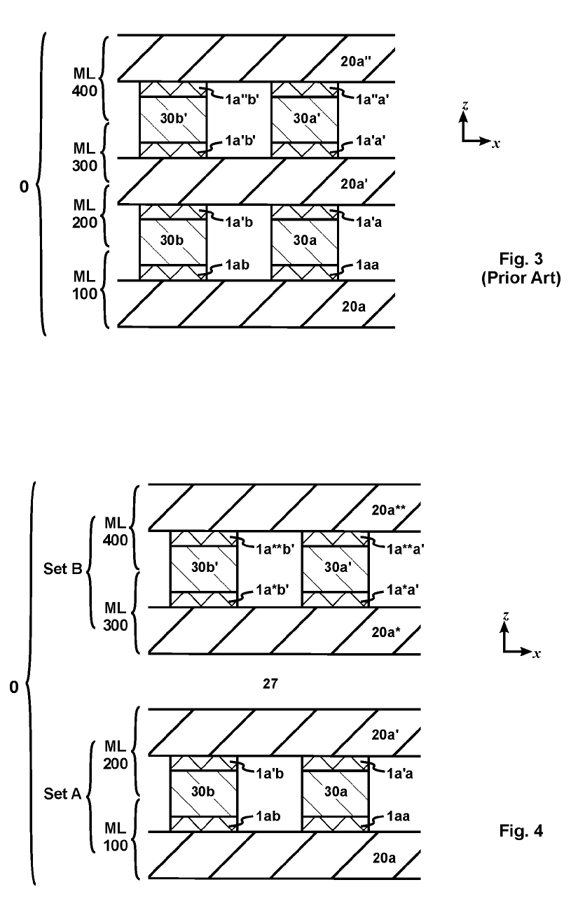

FIG. 3 illustrates an interleaved 3D-M. It comprises four memory levels 100-400 (i.e. m=4) and there is no inter-level dielectric between adjacent memory levels (e.g. 100, 200). The adjacent memory levels (e.g. 100, 200) share address-selection lines (e.g. 30a, 30b).

In comparison, the separated 3D-M is more immune to read/write error and therefore, has a simpler peripheral circuit than the interleaved 3D-M; on the other hand, the interleaved 3D-M has a more compact structure and therefore, has a larger storage capacity and lower manufacturing cost than the separated 3D-M. The interleaved 3D-M is more suitable for the 3D-M with small m (e.g. m<4). For the 3D-M with large m (e.g. m≧4), the interleaved 3D-M may not work, because its memory levels are not electrically separated and leakage current between memory levels could be so large as to interfere with the read/write process.

In order to increase storage capacity, lower manufacturing cost and simplify peripheral circuit, both strengths of the separated 3D-M and interleaved 3D-M are preferably combined, particularly for the 3D-M with large m. Accordingly, the present invention discloses a hybrid-level three-dimensional memory (HL-3DM).

### OBJECTS AND ADVANTAGES

It is a principle object of the present invention to provide a three-dimensional memory with a larger storage capacity.

It is a further object of the present invention to provide a 3D-M with a lower manufacturing cost.

It is a further object of the present invention to provide a 3D-M with a simpler peripheral circuit.

In accordance with these and other objects of the present invention, a hybrid-level three-dimensional memory (HL-3DM) is disclosed.

### SUMMARY OF THE INVENTION

The present invention discloses a hybrid-level three-dimensional memory (HL-3DM). It comprises m memory levels, where m is the total number of memory levels. Among m memory levels, some of them are separated, i.e. there is an inter-level dielectric between adjacent memory levels; while others are interleaved, i.e. adjacent memory levels share address-selection lines. The HL-3DM combines both strengths of the separated 3D-M and interleaved 3D-M: the separated 3D-M is more immune to read/write error and therefore, can use a simpler peripheral circuit; while the interleaved 3D-M has a more compact structure and therefore, has a larger storage capacity and lower manufacturing cost. The HL-3DM is particularly suitable for 3D-M with large m (e.g. m≧4).

### BRIEF DESCRIPTION OF THE PREFERRED EMBODIMENTS

FIG. 1 is a perspective view of a prior-art three-dimensional memory (3D-M);

FIG. 2 is a cross-sectional view of a prior-art separated 3D-M;

FIG. 3 is a cross-sectional view of a prior-art interleaved 3D-M;

FIG. 4 is a cross-sectional view of a preferred 2+2 HL-3DM;

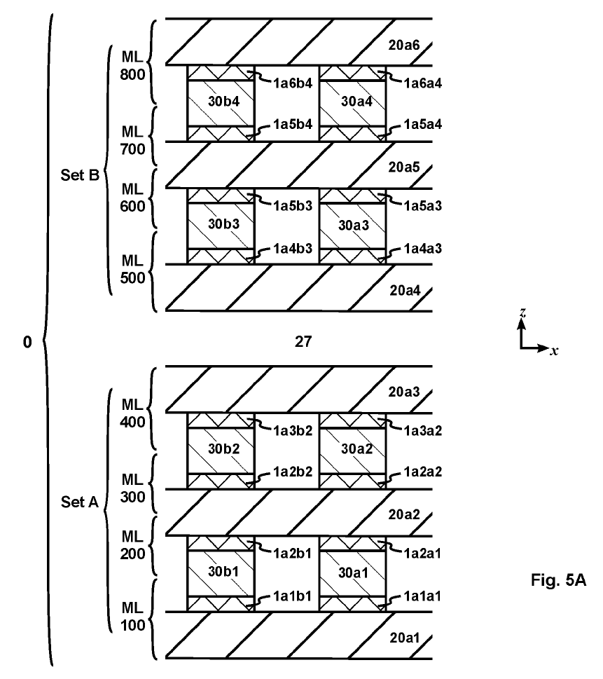

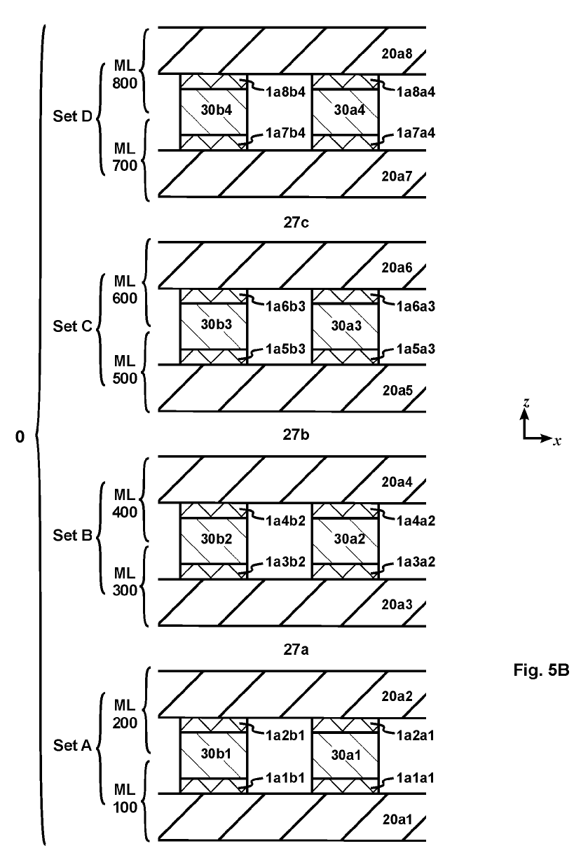

FIG. 5A is a cross-sectional view of a preferred 4+4 HL-3DM; FIG. 5B is a cross-sectional view of a preferred 2+2+2+2 HL-3DM;

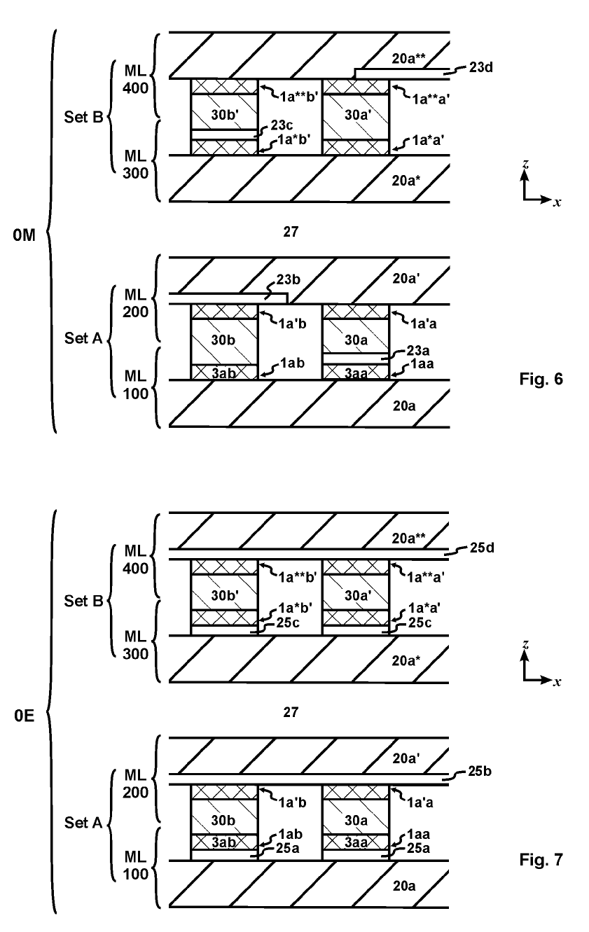

FIG. 6 is a cross-sectional view of a preferred HL-3D-MPM;

FIG. 7 is a cross-sectional view of a preferred HL-3D-EPM;

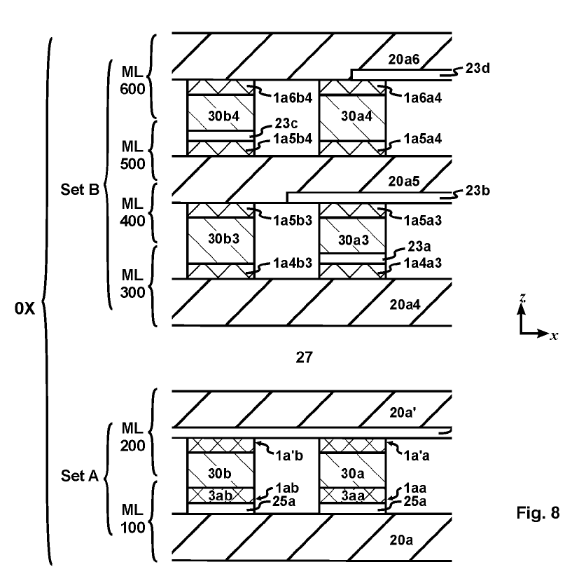

FIG. 8 is a cross-sectional view of a preferred mixed HL3DM.

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

The present invention discloses a hybrid-level three-dimensional memory (HL-3DM). It comprises m memory levels, where m is the total number of memory levels. Among m memory levels, some of them are separated, i.e. there is an inter-level dielectric between adjacent memory levels; while others are interleaved, i.e. adjacent memory levels share address-selection lines. The HL-3DM combines both strengths of the separated 3D-M and interleaved 3D-M: the separated 3D-M is more immune to read/write error and therefore, can use a simpler peripheral circuit; while the interleaved 3D-M has a more compact structure and therefore, has a larger storage capacity and lower manufacturing cost. The HL-3DM is particularly suitable for 3D-M with large m (e.g. m≧4).

FIG. 4 illustrates a preferred HL-3DM 0 comprising four memory levels 100-400 (i.e. m=4). These four memory levels are divided into two memory sets: Set A and Set B. Set A comprises memory levels 100, 200; and Set B comprises memory levels 300, 400. Within each memory set, memory levels are interleaved and adjacent memory levels share address-selection lines; between each memory set, memory levels are separated by an inter-level dielectric. To be more specific, in Set A, memory level 100 comprises first address-selection lines 20a . . . , second address-selection lines 30a, 30b . . . and memory cells 1aa, 1ab . . . ; memory level 200 comprises first address-selection lines 20a′ . . . , second address-selection lines 30a, 30b . . . and memory cells 1a′a, 1a′b . . . ; and memory levels 100, 200 share the second address-selection lines 30a, 30b . . . . In Set B, memory level 300 comprises first address-selection lines 20a* . . . , second address-selection lines 30a′, 30b′ . . . and memory cells 1a*a′, 1a*b′ . . . ; memory level 400 comprises first address-selection lines 20a** . . . , second address-selection lines 30a′, 30b′ . . . and memory cells 1a**a′, 1a**b′ . . . ; and memory levels 300, 400 share the second address-selection lines 30a′, 30b′ . . . . Note that Set A is separated from Set B by the inter-level dielectric 27.

In the present invention, the HL-3DM is denoted by the following convention: 1) if it comprises two memory sets, an HL-3DM is denoted as a+b HL-3DM, which means the first memory set comprises a memory levels, while the second memory set comprises b memory levels; 2) if it comprises three memory sets, an HL-3DM is denoted as a+b+c HL-3DM, which means the first memory set comprises a memory levels, the second memory set comprises b memory levels, and the third memory set comprises c memory levels; 3) and so on. Note that within each memory set, memory levels are interleaved and adjacent memory levels share address-selection lines; between each memory set, memory levels are separated by an inter-level dielectric. Based on this convention, the preferred embodiment in FIG. 4 is a 2+2 3D-M.

FIGS. 5A-5B illustrate two preferred HL-3DM comprising eight levels (i.e. m=8). The preferred embodiment of FIG. 5A is a 4+4 HL-3DM. Its memory levels 100-800 are divided into two memory sets: Set A and Set B. Set A comprises four interleaved memory levels 100-400 and within this set, the adjacent memory levels (e.g. 100, 200) share address-selection lines (e.g. 30a1, 30b1); Set B comprises four interleaved memory levels 500-800 and within this set, the adjacent memory levels (e.g. 500, 600) share address-selection lines (e.g. 30a3, 30b3); between two sets, Set A is separated from Set B by an inter-level dielectric 27.

The preferred embodiment of FIG. 5B is a 2+2+2+2 HL-3DM. Its memory levels 100-800 are divided into four memory sets: Sets A-D. Set A comprises two interleaved memory levels 100-200; Set B comprises two interleaved memory levels 300-400, and is separated from Set A by an inter-level dielectric 27a; Set C comprises two interleaved memory levels 500-600, and is separated from set B by an inter-level dielectric 27b; Set D comprises two interleaved memory levels 700-800, and is separated from Set C by an inter-level dielectric 27c.

The memory levels in the HL-3DM could be either mask-programmable or electrically-programmable. In a mask-programmable HL-3DM (i.e. HL-3D-MPM, referring to FIG. 6), all of its memory levels are mask-programmable; in an electrically-programmable HL-3DM (i.e. HL-3D-EPM, referring to FIG. 7), all of its memory levels are electrically-programmable. On the other hand, a mixed HL-3DM (referring to FIG. 8) could comprise both mask-programmable memory levels and electrically-programmable memory levels.

FIG. 6 illustrates a preferred 2+2 hybrid-level 3D-MPM (HL-3D-MPM) 0M. This preferred embodiment is a special case of FIG. 4 and all of its memory levels are mask-programmable. To be more specific, its memory cell (e.g. 1aa, 1ab . . . ) comprises diode layer 3aa, 3ab . . . and info-dielectric 23a, 23b . . . . If the memory cell stores “1”, there exists an opening in the info-dielectric of the memory cell; if it stores “0”, there is no opening in the info-dielectric. This 3D-MPM uses a number of ways to increase the storage capacity and lower the manufacturing cost, including: 1) nF-opening (n>1), i.e. the dimension of the opening is larger than the width F of the address line (referring to U.S. Pat. No. 6,903,427); 2) N-ary MPM (N>2), i.e. each MPM cell has N possible states and stores more than one bit (referring to U.S. patent application Ser. No. 11/162,262); 3) three-dimensional memory module, i.e. the memory module comprises a plurality of vertically stacked memory chips (referring to U.S. Patent Application 60/767,573).

FIG. 7 illustrates a preferred 2+2 hybrid-level 3D-EPM (HL-3D-EPM) 0E. This preferred embodiment is another special case of FIG. 4 and all of its memory levels are electrically-programmable. To be more specific, its memory cell (e.g. 1aa, 1ab . . . ) comprises antifuse layer (e.g. 25a, 25b . . . ) and diode layer (e.g. 3aa, 3ab . . . ). The antifuse layer has a large resistance before programming, and has a lower resistance after programming.

FIG. 8 illustrates a preferred 2+4 mixed hybrid-level 3D-M (mixed HL-3DM) 0X. It comprise two memory sets A and B, with memory set A comprising two memory levels and memory set B comprising four memory levels. Its memory levels are mixed. To be more specific, the memory levels in memory set A are electrically-programmable, while the memory levels in memory set B are mask-programmable. Similar to FIG. 7, the electrically-programmable memory cells comprise antifuse layer and diode layer. On the other hand, similar to FIG. 6, the mask-programmable memory cells comprise diode layer and info-dielectric, which has openings at selected locations.

While illustrative embodiments have been shown and described, it would be apparent to those skilled in the art that may more modifications than that have been mentioned above are possible without departing from the inventive concepts set forth therein. For example, the preferred HL-3DM may comprise active devices such as transistors (e.g. thin-film transistors). Moreover, m could be larger than 8, e.g. it could be 12, 16 . . . . The invention, therefore, is not to be limited except in the spirit of the appended claims.

What is claimed is:

1. A hybrid-level three-dimensional memory (HL-3DM), comprising:
a substrate including transistors;
a first memory level above said substrate;
a second memory level above said first memory level, wherein said first and second memory levels share at least one address-selection line;
a third memory level adjacent to said first or second memory level, wherein said third memory level does not share address-selection line with either said first memory level or second memory level.

2. The HL-3DM according to claim 1, wherein the total number of memory levels in said 3D-M is no less than 4.

3. The HL-3DM according to claim 1, wherein all of said memory levels are mask-programmable or electrically-programmable.

4. The HL-3DM according to claim 1, wherein selected ones of said memory levels are mask-programmable and the other ones of said memory levels are electrically-programmable.

5. The HL-3DM according to claim 1, wherein at least one of said first, second and third memory levels comprises active devices.

6. The HL-3DM according to claim 5, wherein said active devices comprise transistors.

7. The HL-3DM according to claim 1, wherein at least one of said first, second and third memory levels comprises passive devices.

8. The HL-3DM according to claim 7, wherein said passive devices comprise diodes.

9. A hybrid-level three-dimensional memory (HL-3DM), comprising:
a substrate including transistors;
a first memory level above said substrate;
a second memory level above said first memory level, wherein said first and second memory levels share at least one address-selection line;
a third memory level above said second memory level, wherein said third memory level is separated from said second memory level by an inter-level dielectric.

10. The HL-3DM according to claim 9, wherein the number of memory levels in said 3D-M is no less than 4.

11. The HL-3DM according to claim 10, wherein all of said memory levels are mask-programmable or electrically-programmable.

12. The HL-3DM according to claim 10, wherein selected ones of said memory levels are mask-programmable and the other ones of said memory levels are electrically-programmable.

13. The HL-3DM according to claim 9, wherein at least one of said first, second and third memory levels comprises active devices.

14. The HL-3DM according to claim 9, wherein at least one of said first, second and third memory levels comprises passive devices.

15. A hybrid-level three-dimensional memory (HL-3DM), comprising:
a substrate including transistors;
a first memory level above said substrate;
a second memory level above said first memory level, wherein said first memory level is separated from second memory level by an inter-level dielectric;
a third memory level above said second memory level, wherein said second and third memory levels share at least one address-selection line.

16. The HL-3DM according to claim 15, wherein the number of memory levels in said 3D-M is no less than 4.

17. The HL-3DM according to claim 15, wherein all of said memory levels are mask-programmable or electrically-programmable.

18. The HL-3DM according to claim 15, wherein selected ones of said memory levels are mask-programmable and the other ones of said memory levels are electrically-programmable.

19. The HL-3DM according to claim 15, wherein at least one of said first, second and third memory levels comprises active devices.

20. The HL-3DM according to claim 15, wherein at least one of said first, second and third memory levels comprises passive devices.
